(19) United States
(12) Patent Application Publication
(10) Pub. No.: US 2025/0355046 A1
(43) Pub. Date: Nov. 20, 2025

(54) METHOD FOR ESTIMATING A TRIP INTENSITY OF A CIRCUIT BREAKER, SYSTEM, ASSEMBLY, AND ASSOCIATED COMPUTER PROGRAM

(71) Applicant: Schneider Electric Industries SAS, Rueil-Malmaison (FR)

(72) Inventors: David Lanes, Saint Hilaire du Touvet (FR); Nicolas Wenzel, Grenoble (FR)

(73) Assignee: Schneider Electric Industries SAS, Rueil-Malmaison (FR)

(21) Appl. No.: 19/206,205

(22) Filed: May 13, 2025

(30) Foreign Application Priority Data
May 17, 2024 (FR) 2405090

(51) Int. Cl. G01R 31/333; G01H 3/12; H01H 71/04

(52) U.S. Cl. CPC G01R 31/3333; G01H 3/12; H01H 71/04

(57) ABSTRACT

This invention relates to a method for estimating a trip intensity of a circuit breaker, the circuit breaker being configured to switch from an armed configuration to a tripped configuration, a trip current, with an intensity equal to the trip intensity, flowing in the circuit breaker when same switches to the tripped configuration, the switching of the circuit breaker to the tripped configuration generating a sound, representative of the trip intensity, the method comprising at least the following steps:
acquisition (102) of an output signal (Sₒ) emitted by a microphone, the output signal being representative of the sound generated by the circuit breaker when same switches to the tripped configuration;
calculation (108) of a plurality of metrics from the output signal (Sₒ); and
determination (110) of a trip intensity class via an artificial intelligence model, the trip intensity class being chosen among a plurality of predetermined trip intensity classes.

### FIELD

This invention relates to a method for estimating a trip intensity of a circuit breaker, a system, an assembly, and an associated computer program.

### BACKGROUND

In order to monitor the operation of a circuit breaker and predict maintenance operations, it is known to measure the current intensity flowing through the circuit breaker at the moment it trips, i.e., becomes electrically isolating. The current flowing through the circuit breaker at the moment same trips is called the trip current, and has an intensity known as the trip intensity.

However, measuring the trip intensity is costly and intrusive, as it requires adding a current sensor inside the circuit breaker, specifically on one of the conductors of the circuit breaker, which must be able to withstand high trip intensities.

### SUMMARY

The aim of the invention is to propose a detection method and system allowing the trip intensity to be estimated in a simple, non-intrusive, and low-cost manner.

To this end, the invention relates to a method for estimating a trip intensity of a circuit breaker, the circuit breaker being able to be connected between a source and a load, the circuit breaker being configured to switch from an armed configuration, wherein the circuit breaker conducts a current flowing between the source and the load, to a tripped configuration, wherein the circuit breaker electrically isolates the load from the source, a trip current, with an intensity equal to the trip intensity, flowing in the circuit breaker when same switches to the tripped configuration, the switching of the circuit breaker to the tripped configuration generating a sound, representative of the trip intensity, the method comprising at least the following steps, implemented by an electronic control module:
acquisition of an output signal emitted by a microphone, the output signal being representative of the sound generated by the circuit breaker when same switches to the tripped configuration;
calculation of a plurality of metrics from the output signal; and
determination of a trip intensity class via an artificial intelligence model, previously trained by machine learning to provide, from the plurality of metrics, the trip intensity class associated with the trip current, the trip intensity class being chosen among a plurality of predetermined trip intensity classes, each trip intensity class corresponding to a trip intensity range.

By means of the invention, the estimation of the intensity is simplified. Indeed, using sound to determine the trip intensity does not require complex or intrusive measurements, e.g. inside the circuit breaker or on the contacts of the circuit breaker. The method is thus easy to implement and non-intrusive. Moreover, using an artificial intelligence model simplifies the determination of the trip intensity compared to traditional signal analysis and processing methods, thus limiting the complexity of the method.

According to other advantageous aspects of the invention, the method comprises one or more of the following features, taken alone or in any technically possible combination:
The method further comprises a step of filtering the output signal.
The method further comprises a step of normalizing to normalize the amplitude of the output signal.
The calculation of the plurality of metrics comprises the calculation of a plurality of Mel scale cepstral coefficients from the output signal.
The plurality of trip intensity classes is formed of five trip intensity classes, each trip intensity class corresponding to a trip intensity range distinct from the other trip intensity classes.
The artificial intelligence model is a random forest.
The method further comprises a step of transmitting the determined trip intensity class to an emission module.
The method further comprises a step of assigning a so-called maximum trip intensity class to the trip current if the microphone saturates during the acquisition of the sound.

The invention also relates to a system for estimating a trip intensity of a circuit breaker, the circuit breaker being able to be connected between a source and a load, the circuit breaker being configured to switch from an armed configuration, wherein the circuit breaker conducts a current flowing between the source and the load, to a tripped configuration, wherein the circuit breaker electrically isolates the load from the source, a trip current with an intensity equal to the trip intensity flowing in the circuit breaker when same switches to the tripped configuration, the switching of the circuit breaker to the tripped configuration generating a sound, representative of the trip intensity, the system comprising:
a microphone, configured to acquire the sound generated by the circuit breaker when same switches to the tripped configuration and to emit an output signal, the output signal being representative of the sound;
an electronic control module, configured to receive the output signal, the electronic control module comprising:
   a calculation unit configured to calculate a plurality of metrics from the output signal; and
   a determination unit, configured to determine a trip intensity class via an artificial intelligence model, previously trained by machine learning to provide, from the plurality of metrics, the trip intensity class associated with the trip current, the trip intensity class being chosen among a plurality of predetermined trip intensity classes, each trip intensity class corresponding to a trip intensity range.

The invention also relates to an electrical assembly comprising:
a circuit breaker, able to be connected between a source and a load, the circuit breaker being configured to switch from an armed configuration, wherein the circuit breaker conducts a current flowing between the source and the load, to a tripped configuration, wherein the circuit breaker electrically isolates the load from the source, when a trip current with an intensity equal to a trip intensity flows in the circuit breaker, the switching of the circuit breaker to the tripped configuration generating a sound representative of the trip intensity, the circuit breaker comprising a case; and
an estimation system, fixed to the case.

The invention also relates to a computer program comprising software instructions which, when executed by a microcontroller, implement an estimation method as defined above.

### BRIEF DESCRIPTION OF THE DRAWINGS

The invention will become clearer upon reading the following description, given solely by way of non-limiting example, and made with reference to the drawings in which:

FIG. 1 is a diagram of an electrical assembly according to an embodiment of the invention;

FIG. 2 is a diagram of an electronic control module according to an embodiment of the invention;

FIG. 3 is a flowchart of an estimation method according to an embodiment of the invention;

FIG. 4 is a graph of an output signal.

### DETAILED DESCRIPTION

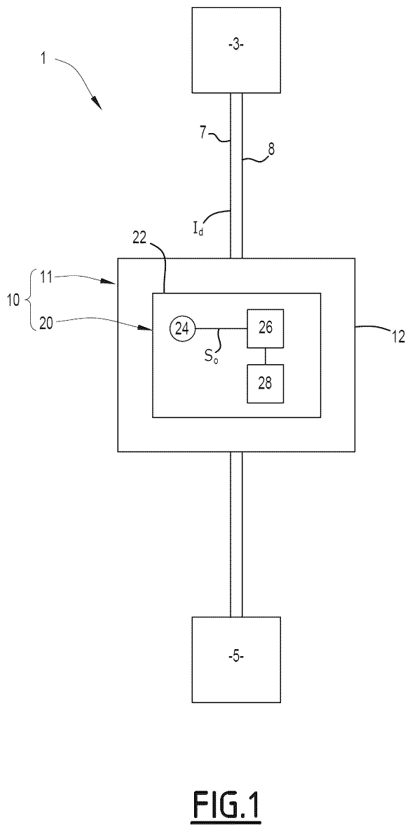

FIG. 1 represents an electrical installation 1. The electrical installation 1 comprises a source 3 and a load 5, electrically connected by a phase conductor 7 and a neutral conductor 8. The source 3 provides electricity and is, e.g., an electrical generator, a transformer, or an electrical network, such as a mains electrical network. The load 5 is a device consuming electricity, such as a domestic electrical appliance, an industrial equipment item such as an electric motor, or a server. An electric current, simply called current hereafter, flows between the source 3 and the load 5 through the phase conductor 7 and returns to the source 3 via the neutral conductor 8.

The current is advantageously a low voltage current, meaning a nominal voltage of the current is less than 1500V. The current is an alternating current, or alternatively, a direct current.

The electrical installation 1 comprises an electrical assembly 10. The electrical assembly 10 comprises a circuit breaker 11, connected between the source and the load. The circuit breaker 11 is, e.g., a molded case circuit breaker, or MCCB. The circuit breaker 11 comprises a case 12, which is made of an electrically insulating material. The case 12 contains most of the other components of the circuit breaker 11, comprising the circuit breaker contacts, not shown.

The circuit breaker 11 is configured to switch between an armed configuration, wherein the contacts are closed, and wherein said circuit breaker conducts the current flowing between the source 3 and the load 5, and a tripped configuration, wherein the contacts are open and wherein said circuit breaker electrically isolates the source 3 from the load 5. The circuit breaker 11 is configured to switch to the tripped configuration in case of a short circuit or overload of the electrical installation 1, to prevent an excessive current from flowing in the electrical installation 1. The circuit breaker 11 is also configured to switch to the tripped configuration following a user command, e.g., manually switching said circuit breaker to the tripped configuration by operating a lever of the circuit breaker 11. When the circuit breaker 11 switches to the tripped configuration, the current flowing in the circuit breaker 11 is called the trip current, which has an intensity equal to a trip intensity I_{d}.

The electrical assembly 10 further comprises a system 20 for estimating the trip intensity I_{d} of the circuit breaker 11. The estimation system 20 is fixed to the case 12, e.g., by being glued or screwed onto the case 12. Advantageously, the estimation system 20 comprises a casing 22 that is fixed onto the case 12.

The estimation system comprises a microphone 24, an electronic control module 26, connected to the microphone 24, and an emission module 28, connected to the electronic control module 26, advantageously housed inside the casing 22.

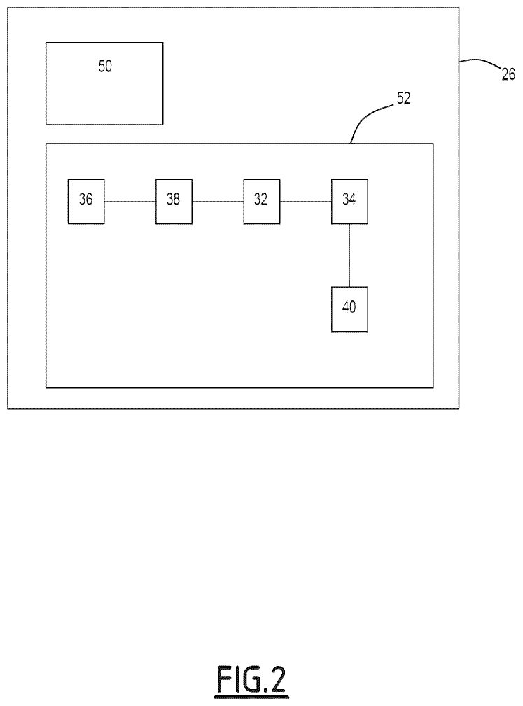

The electronic control module 26 comprises a calculation unit 32 connected to a determination unit 34, as shown in FIG. 2. Advantageously, the electronic control module 26 further comprises a filtering unit 36, connected to a normalization unit 38, connected to the calculation unit 32. Advantageously, the electronic control module 26 further comprises a transmission unit 40, connected to the determination unit 34.

In the example of FIG. 2, the electronic control module 26 is formed, e.g., by a processor 50 and a memory 52, associated with the processor 50. In the example of FIG. 2, the calculation unit 32 and the determination unit 34, as well as optionally the filtering unit 36, the normalization unit 38, and the transmission unit 40, are each implemented as software, or a software module, executable by the processor 50. The memory of the electronic control module 26 is then able to store a calculation software and a determination software, as well as optionally a filtering software, a normalization software, and a transmission software. The processor is then able to execute each of the software among the calculation software and the determination software, as well as optionally the filtering software, the normalization software, and the transmission software.

Alternatively, the calculation unit 32 and the determination unit 34, as well as optionally the filtering unit 36, the normalization unit 38, and the transmission unit 40, are each implemented as a programmable logic component, such as an FPGA (Field Programmable Gate Array), or an integrated circuit, such as an ASIC (Application Specific Integrated Circuit).

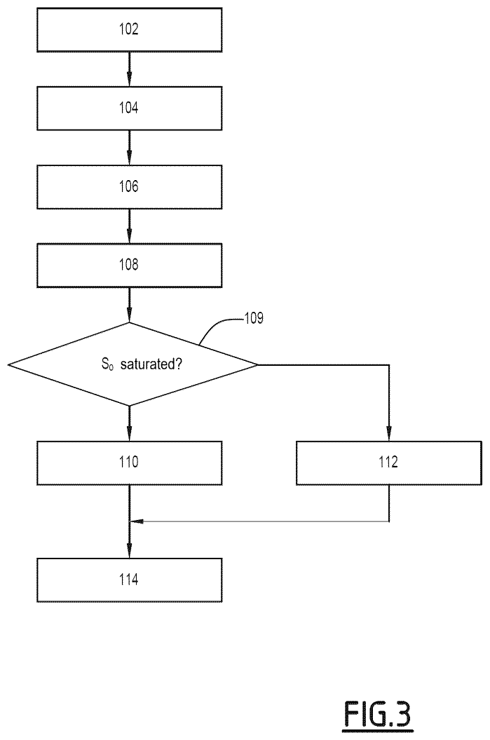

Alternatively, when the electronic control module 26 is implemented as one or more software, i.e., as a computer program, also called a computer program or computer program product, it is also able to be recorded on a medium, not shown, readable by a computer, or by a microcontroller. The readable medium is, e.g., a medium capable of storing electronic instructions and being coupled to a bus of a computer system. E.g., the readable medium is an optical disk, a magneto-optical disk, a ROM memory, a RAM memory, any type of non-volatile memory (e.g., FLASH or NVRAM), or a magnetic card. On the readable medium a computer program is then stored comprising software instructions, which, when executed by a microcontroller, implement a method for estimating the trip intensity I_{d} of the circuit breaker 11 described in detail below, and with reference to FIG. 3.

When the circuit breaker 11 switches to the tripped configuration, it generates a sound. By sound, is meant mechanical vibrations that propagate in the air, and not in a solid medium, such as the case 12. The sound is caused, e.g., by the appearance of an electric arc between the contacts at the moment of their opening, then by the dissipation of this arc, as well as by the movement of the contacts of the circuit breaker 11. In the case of an opening by the user without current in the contacts of the circuit breaker 11, the sound is caused only by the movement of the contacts of the circuit breaker 11. Thus, the sound is representative of the trip intensity I_{d}.

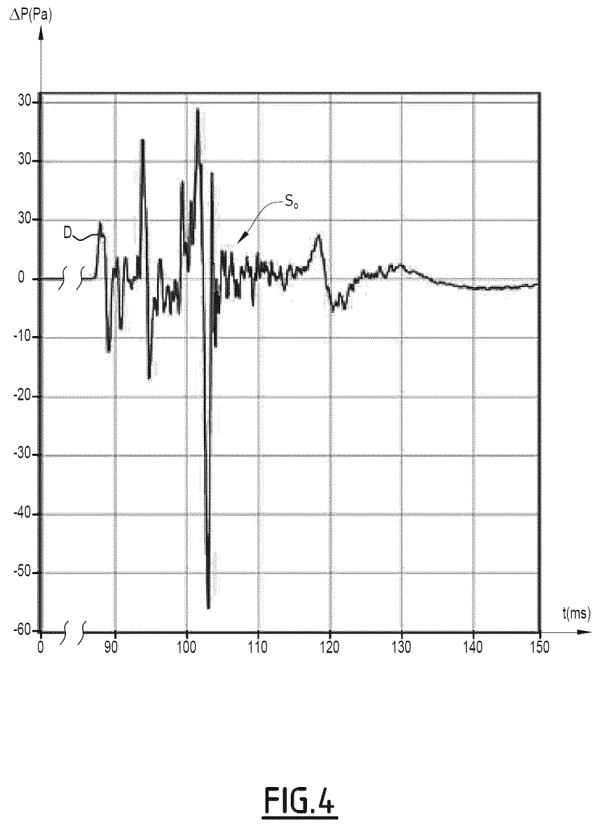

The microphone 24 acquires the sound generated by the circuit breaker 11 when same switches from the armed configuration to the tripped configuration and emits an output signal Sₒ. The output signal Sₒ, represented in FIG. 4, is representative of the sound generated by the circuit breaker 11, and thus of the trip intensity I_{d}.

In practice, the microphone 24 continuously acquires the sound generated by the circuit breaker and continuously emits a physical quantity, e.g., a voltage or voltage modulation, a current whose amplitude is directly proportional to the sound acquired by the microphone 24. As long as the sound acquired by the microphone 24 corresponds to a pressure variation ΔP strictly less than a pressure threshold, this physical quantity does not comprise any information related to the trip intensity I_{d}. The pressure threshold is, e.g., equal to 1 Pa. By equal to a value, it is meant equal to this value plus or minus 1% of this value.

When the sound acquired by the microphone 24 corresponds to a pressure variation ΔP greater than or equal to the pressure threshold, the physical quantity forms an output signal Sₒ, which is then representative of the sound generated by the circuit breaker 11, and thus of the trip intensity I_{d}. The output signal Sₒ comprises a trip event D, which is associated with the sound corresponding to the pressure variation greater than or equal to the pressure threshold.

Advantageously, the output signal Sₒ is of a duration less than or equal to 200 ms, e.g. equal to 150 ms, centered around the trip event. Alternatively, the output signal Sₒ has a duration equal to 150 ms, the trip event being 100 ms from the start of the output signal Sₒ.

Advantageously, the output signal Sₒ is sampled at a frequency less than or equal to 30 kHz, e.g. equal to 24 KHz.

The method for estimating the trip intensity I_{d} of the circuit breaker 11, an embodiment of which is described below with reference to FIG. 3, implements an estimation of the trip intensity I_{d} from the sound caused by the trip and captured by the microphone 24. The steps of the method described below are implemented by the electronic control module 26.

The electronic control module 26 acquires the output signal Sₒ during a step 102.

Advantageously, the electronic control module 26 performs a step 104 of filtering the output signal Sₒ. For example, the electronic control module 26 performs a high-pass filtering, e.g. with a cutoff frequency at 30 Hz and a low-pass filtering, e.g. with a cutoff frequency at 10 KHz. The step 104 of filtering is advantageously implemented by the filtering unit 36.

Advantageously, the electronic control module 26 performs a step of amplitude normalization 106 of the output signal Sₒ. Advantageously, the step 106 is implemented by the normalization unit 38.

The electronic control module 26 calculates a plurality of metrics from the output signal Sₒ, advantageously filtered and normalized, at step 108. More precisely, step 108 is implemented by the calculation unit 32.

Advantageously, the plurality of metrics is a plurality of Mel Frequency Cepstral Coefficients, or MFCC. For example, the MFCC are calculated on five sliding windows, 13 MFCC being calculated for each window, forming a total of 65 coefficients calculated from the output signal Sₒ.

In a variant, the plurality of metrics comprises an RMS or Root Mean Square value, or quadratic mean of the output signal Sₒ, a magnitude of the output signal Sₒ, i.e., the maximum in absolute value of the output signal Sₒ, an average frequency of the output signal Sₒ. The average frequency of the output signal Sₒ is related to the current flowing in the circuit breaker 11, high frequencies being associated with a low current, e.g. less than 250 A, and low frequencies being associated with a high current, e.g. greater than 2500 A.

Advantageously, the electronic control module 26 determines if the output signal Sₒ is saturated at step 109, e.g. by recognizing the saturation modes of the microphone 24 by analyzing the metrics of the signal Sₒ or by analyzing the MFCC. More precisely, step 109 is implemented by the determination unit 34.

If the output signal Sₒ is not saturated, the electronic control module 26 determines, during a step 110, advantageously implemented by the determination unit 34, a trip intensity class associated with the trip current, via an artificial intelligence model. The artificial intelligence model is, e.g., a random forest, but alternatively, is a support vector machine model, or SVM, a k-nearest neighbors model, or k-NN, or a neural network. The artificial intelligence model is previously trained by machine learning, as described in more detail hereinbelow.

The artificial intelligence model takes as input the plurality of metrics, and provides, from the plurality of metrics, the trip intensity class associated with the trip current. According to an example, the artificial intelligence model provides the majority intensity class, the trip intensity class associated with the trip current being the class with the highest probability of belonging.

The trip intensity class is chosen among a plurality of trip intensity classes, also simply called classes. The trip intensity classes are predetermined, e.g. by the manufacturer of the system 20, and each trip intensity class corresponds to a trip intensity range. For example, the trip intensity classes are five in number and the intensity range of each class is distinct from that of the other classes. E.g.:
a first class corresponds to a trip intensity I_{d} of zero,
a second class corresponds to a trip intensity I_{d} strictly between 0 and 250 A,
a third class corresponds to a trip intensity I_{d} greater than or equal to 250 A and strictly less than 2500 A,
a fourth class corresponds to a trip intensity I_{d} greater than or equal to 2500 A and strictly less than 5000 A, and
a fifth class corresponds to a trip intensity I_{d} greater than or equal to 5000 A.

The first and second classes correspond in particular to an opening following a user command, the third class corresponds in particular to a trip of the circuit breaker 11 following an overload. The fourth and fifth classes correspond, e.g., to short circuits.

Alternatively, the plurality of classes is formed of more or less than five classes.

If, during step 109, the electronic control module 26, or advantageously, the determination unit 34, determines that the output signal Sₒ is saturated, then said electronic control module directly assigns to the trip current, a so-called maximum trip intensity class during a step 112. The maximum intensity class corresponds to the class with the highest intensity range. For example, in the case of the five classes described above, the maximum trip intensity class is the fifth class, corresponding to a trip intensity I_{d} greater than 5000 A.

Advantageously, the electronic control module 26 transmits the trip intensity class to the emission module 28 during a step 114. Step 114 is advantageously implemented by the transmission unit 40. The emission module 28 is, e.g., connected, via a wired or wireless connection, e.g. via Wifi or Bluetooth, to a terminal external to the estimation system 10, not shown, and following the transmission of the trip intensity class by the electronic control module, emits the trip intensity class, which is received by the terminal and displayed, e.g. in the form of a message, on the terminal. For example, the emission module 28 is a Wifi or Bluetooth box. A user or technician is thus informed of the trip intensity I_{d} during the tripping of the circuit breaker 11, which advantageously allows them to assess the severity of the electrical fault that caused the circuit breaker 11 to switch to the tripped configuration, to estimate the state of the circuit breaker and/or to plan predictive maintenance operations, on the circuit breaker 11 or on the installation 1 more generally.

The artificial intelligence model is trained by supervised machine learning. For example, a plurality of output signals corresponding to different trip intensities are recorded in a database. The output signals are then advantageously filtered. Advantageously, to take into account a possible deformation of the sound generated by the circuit breaker 11, caused by temperature variations in the environment in which the circuit breaker 11 operates, a random noise between −3 dB and +3 dB is added to each filtered output signal, to form a plurality of noisy output signals. The noisy output signal is then advantageously normalized in amplitude, and then the metrics, e.g., the MFCC are calculated for each noisy output signal. The MFCC of each noisy output signal form the training data for the artificial intelligence model.

Advantageously, to increase the amount of training data and/or to balance the collected data between each class, data augmentation methods are used, such as the Synthetic Minority Over-Sampling Technique, also called SMOTE. The model is then trained on the training data, and advantageously, validated, e.g. by a cross-validation method.

Advantageously, particularly in the case where the artificial intelligence model is a random forest, the model is trained with a bagging method.

The normalization step 106 allows the same estimation system 20, implementing the previously described method, to be used on different circuit breakers, e.g. on two-pole circuit breakers and on three-pole circuit breakers.

1. A method for estimating a trip intensity of a circuit breaker, the circuit breaker being able to be connected between a source and a load, the circuit breaker being configured to switch from an armed configuration, wherein the circuit breaker conducts a current flowing between the source and the load, to a tripped configuration, wherein the circuit breaker electrically isolates the load from the source, a trip current, with an intensity equal to the trip intensity, flowing in the circuit breaker when same switches to the tripped configuration, the switching of the circuit breaker to the tripped configuration generating a sound, representative of the trip intensity, the method comprising at least the following steps, implemented by an electronic control module:
acquisition of an output signal emitted by a microphone, the output signal being representative of the sound generated by the circuit breaker when same switches to the tripped configuration;
calculation of a plurality of metrics from the output signal; and
determination of a trip intensity class via an artificial intelligence model, previously trained by machine learning to provide, from the plurality of metrics, the trip intensity class associated with the trip current, the trip intensity class being chosen among a plurality of predetermined trip intensity classes, each trip intensity class corresponding to a trip intensity range.

2. The method according to claim 1, further comprising a step of filtering the output signal.

3. The method according to claim 1, further comprising a step of normalizing to normalize the amplitude of the output signal.

4. The method according to claim 1, wherein the calculation of the plurality of metrics comprises the calculation of a plurality of Mel scale cepstral coefficients from the output signal.

5. The method according to claim 1, wherein the plurality of trip intensity classes is formed of five trip intensity classes, each trip intensity class corresponding to a trip intensity range distinct from the other trip intensity classes.

6. The method according to claim 1, wherein the artificial intelligence model is a random forest.

7. The method according to claim 1, further comprising a step of transmitting the determined trip intensity class to an emission module.

8. The method according to claim 1, further comprising a step of assigning a so-called maximum trip intensity class to the trip current if the microphone saturates during the acquisition of the sound.

9. A system for estimating a trip intensity of a circuit breaker, the circuit breaker being able to be connected between a source and a load, the circuit breaker being configured to switch from an armed configuration, wherein the circuit breaker conducts a current flowing between the source and the load, to a tripped configuration, wherein the circuit breaker electrically isolates the load from the source, a trip current with an intensity equal to the trip intensity flowing in the circuit breaker when same switches to the tripped configuration, the switching of the circuit breaker to the tripped configuration generating a sound, representative of the trip intensity, the system comprising:
a microphone, configured to acquire the sound generated by the circuit breaker when same switches to the tripped configuration and to emit an output signal, the output signal being representative of the sound;
an electronic control module, configured to receive the output signal, the electronic control module comprising:
a calculation unit configured to calculate a plurality of metrics from the output signal; and
a determination unit, configured to determine a trip intensity class via an artificial intelligence model, previously trained by machine learning to provide, from the plurality of metrics, the trip intensity class associated with the trip current, the trip intensity class being chosen among a plurality of predetermined trip intensity classes, each trip intensity class corresponding to a trip intensity range.

10. An electrical assembly comprising:
a circuit breaker, able to be connected between a source and a load, the circuit breaker being configured to switch from an armed configuration, wherein the circuit breaker conducts a current flowing between the source and the load, to a tripped configuration, wherein the circuit breaker electrically isolates the load from the source, when a trip current with an intensity equal to a trip intensity flows in the circuit breaker, the switching of the circuit breaker to the tripped configuration generating a sound representative of the trip intensity, the circuit breaker comprising a case; and
an estimation system according to claim 9, fixed to the case.

11. A computer program comprising software instructions which, when executed by a microcontroller, implement a method for estimation according to claim 1.
